(19) United States
(12) Patent Application Publication
(10) Pub. No.: US 2026/0052706 A1
(43) Pub. Date: Feb. 19, 2026

(54) SEMICONDUCTOR DEVICE AND METHOD FOR FABRICATING THE SAME

(71) Applicant: SK hynix Inc., Gyeonggi-do (KR)

(72) Inventors: Jeong Myeong KIM, Gyeonggi-do (KR); Cha Deok DONG, Gyeonggi-do (KR); Eun Kyo BYUN, Gyeonggi-do (KR); Dae Hee LEE, Gyeonggi-do (KR); Bo Kyung JUNG, Gyeonggi-do (KR); Keo Rock CHOI, Gyeonggi-do (KR)

(21) Appl. No.: 19/053,419

(22) Filed: Feb. 14, 2025

(30) Foreign Application Priority Data
Aug. 13, 2024 (KR) 10-2024-0108260

(51) Int. Cl. H10B 63/00

(52) U.S. Cl. CPC H10B 63/22

(57) ABSTRACT

Disclosed are a semiconductor device that may improve selector characteristics of memory cells, and a method for fabricating the semiconductor device. The semiconductor device includes a plurality of memory cells. Each of the memory cells includes a memory layer; and a selector layer formed over or below the memory layer to select the memory layer. The selector layer includes an amorphous silicon layer having at least one dopant selected from a group including group-13 elements, group-14 elements, and group-15 elements of periodic table.

### CROSS-REFERENCE TO RELATED APPLICATIONS

The present application claims priority under 35 U.S.C. 119(a) to Korean Patent Application No. 10-2024-0108260, filed on Aug. 13, 2024, which is incorporated herein by reference in its entirety.

### BACKGROUND

### 1. Field

Embodiments of the present disclosure relate to a semiconductor technology, and more particularly, to a semiconductor device including memory cells with a selector, and a method for fabricating the semiconductor device.

### 2. Description of the Related Art

Recently, semiconductor devices capable of storing data in diverse electronic devices, such as computers and portable communication devices, are demanded to cope with the trends of miniaturization, low power consumption, high performance, and diversification of electronic devices, and researchers and the industry are studying to develop such semiconductor devices. The semiconductor devices capable of storing data by taking advantage of the characteristic of switching between different resistance states according to the applied voltage or current may include a Resistive Random Access Memory (RRAM), a Phase-change Random Access Memory (PRAM), a Ferroelectric Random Access Memory (FRAM), a Magnetic Random Access Memory (MRAM), an e-fuse and the like.

A memory device having a variable resistance element may include a selector as an element for selecting a particular memory cell among a plurality of memory cells that are arrayed. The selector may be realized as a thin layer in a memory cell.

### SUMMARY

Embodiments of the present disclosure are directed to a semiconductor device including memory cells with improved selector characteristics, and a method for fabricating the semiconductor device.

In accordance with an embodiment of the present disclosure, a semiconductor device includes a plurality of memory cells, wherein each of the memory cells includes a memory layer; and a selector layer formed over or below the memory layer to select the memory layer, and wherein the selector layer includes an amorphous silicon layer having at least one dopant selected from a group including group-13 elements, group-14 elements, and group-15 elements of periodic table.

In accordance with another embodiment of the present disclosure, a method for fabricating a semiconductor device includes forming an amorphous silicon layer having a dopant as a selector layer over a substrate, the selector layer configured to control electrical access to one memory cell among a plurality of memory cells that are arrayed; and performing a thermal process on the amorphous silicon layer at a temperature less than or equal to a temperature at which the amorphous silicon layer is crystallized.

### BRIEF DESCRIPTION OF THE DRAWINGS

FIG. 1 is a perspective view illustrating a semiconductor device in accordance with an embodiment of the present disclosure.

FIG. 2 is a cross-sectional view illustrating a structure of a selector unit in accordance with an embodiment of the present disclosure.

FIG. 3 illustrates an operation of the selector unit shown in FIG. 2.

FIGS. 4A and 4B are graphs showing Equivalent Oxide Thicknesses (EOT) and leakage indexes of silicon oxide and boron (B)-doped amorphous silicon.

FIG. 5 is a graph showing the dispersions of constituent elements according to X-ray photoelectron spectroscopy (XPS) and electron energy loss spectroscopy (EELS) according to a comparative example and an embodiment of the present disclosure.

FIG. 6A to FIG. 6C are cross-sectional views illustrating a semiconductor device and a fabrication method thereof in accordance with an embodiment of the present disclosure.

### DETAILED DESCRIPTION

Hereinafter, the various embodiments of the present disclosure will be described in detail with reference to the attached drawings.

Embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

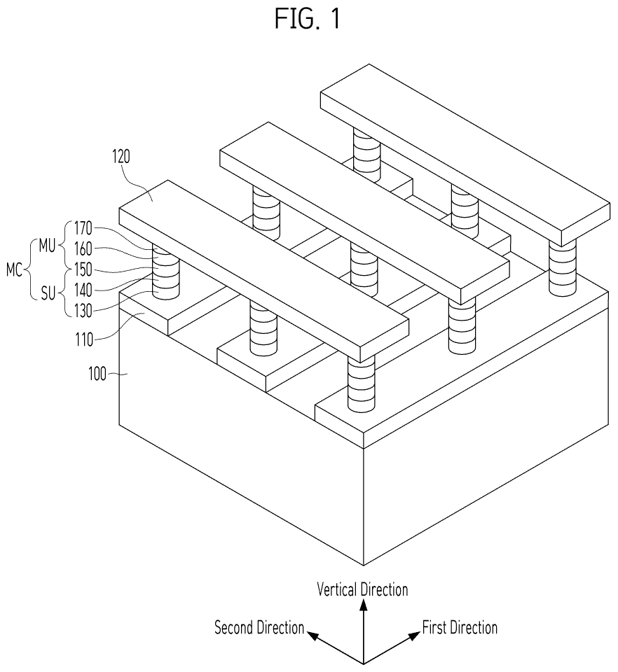

FIG. 1 is a perspective view illustrating a semiconductor device in accordance with an embodiment of the present disclosure.

Referring to FIG. 1, the semiconductor device in accordance with one embodiment of the present disclosure may include a substrate 100, a plurality of first conductive lines 110, a plurality of second conductive lines 120, and a plurality of memory cells MC. The plurality of first conductive lines 110 may be disposed over the substrate 100 and extend in a first direction. The plurality of second conductive lines 120 may be disposed over the first conductive lines 110 and extend in a second direction intersecting with the first direction. The plurality of memory cells MC may be disposed to overlap with the intersection regions between the first conductive lines 110 and the second conductive lines 120. The first direction and the second direction may mean directions substantially parallel to the surface of the substrate 100. Hereinafter, a direction substantially perpendicular to the surface of the substrate 100 will be referred to as a vertical direction.

The substrate 100 may include a semiconductor material, such as silicon. In some embodiments, a predetermined lower structure may be formed in the substrate 100. For example, an integrated circuit for driving a first conductive line 110 and/or a second conductive line 120 may be formed in the substrate 100.

A plurality of first conductive lines 110 may be disposed spaced apart from each other in the second direction. The first conductive lines 110 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or combinations thereof. The first conductive lines 110 may have a single-layer structure or a multi-layer structure.

A plurality of second conductive lines 120 may be disposed spaced apart from each other in the first direction. The second conductive lines 120 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or combinations thereof. The second conductive lines 120 may have a single-layer structure or a multi-layer structure.

Each of the memory cells MC may include a memory unit MU, which is a portion where data are actually stored, and a selector unit SU that controls access to the memory unit MU. Each of the memory cells MC may include multiple electrode layers, i.e., a first electrode layer 130 disposed below a selector layer 140, a second electrode layer 150 and/or a third electrode layer 170, which are disposed over the selector layer 140. For example, the memory cell MC may include a stacked structure of the first electrode layer 130, the selector layer 140, the second electrode layer 150, a memory layer 160, and the third electrode layer 170. The selector unit SU may include the first electrode layer 130, the selector layer 140, and the second electrode layer 150. The memory unit MU may include the second electrode layer 150, the memory layer 160, and the third electrode layer 170. The second electrode layer 150 may be shared by the selector unit SU and the memory unit MU.

The first electrode layer 130 and the third electrode layer 170 may be respectively disposed at both ends of the memory cell MC, that is, at the bottom end and the top end, and may function to supply a voltage or current that is required for an operation of the memory cell MC. The second electrode layer 150 may function to electrically connect the selector layer 140 and the memory layer 160 while physically separating them from each other. The first electrode layer 130, the second electrode layer 150, or the third electrode layer 170 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or combinations thereof. Alternatively, the first electrode layer 130, the second electrode layer 150, or the third electrode layer 170 may include a carbon electrode.

The memory layer 160 may function to store data in diverse ways. For example, the memory layer 160 may include a variable resistance layer that stores different data by switching between different resistance states according to the voltage or current supplied through the upper and lower ends of the memory layer 160. The variable resistance layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like. For example, the variable resistance layer may include metal oxides, such as transition metal oxides, perovskite-based materials and the like, phase-change materials such as chalcogenide-based materials, ferroelectric materials, ferromagnetic materials, and the like.

The selector layer 140 may be formed as a thin layer in the memory cell. The selector layer 140 may have a function of preventing current leakage that may occur between the memory cells MC that share the first conductive line 110 or the second conductive line 120, while controlling the electrical access to one memory cell among the memory cells that are arrayed. To this end, the selector layer 140 may have a threshold switching characteristic of blocking the current or holding the current to hardly flow when the level of the voltage supplied to the upper and lower ends of the selector layer 140 is less than a threshold voltage level, and then letting the current to rapidly flow at a voltage level greater than or equal to the threshold voltage level. The selector layer 140 may be turned on at a voltage level greater than or equal to the threshold voltage level and turned off at a voltage level less than the threshold voltage level.

Typically, the selector layer 140 may use a dielectric material into which a dopant is implanted. According to one embodiment of the present disclosure, the selector layer 140 may include an amorphous silicon layer that is doped with boron (B). According to another embodiment of the present disclosure, the selector layer 140 may be formed by additionally doping arsenic (As) onto the amorphous silicon layer that is doped with boron (B) through an additional ion implantation process.

According to the embodiments of the present disclosure, the dopant doped into the amorphous silicon layer may be a group-13 element of the periodic table instead of boron (B), and may be a group-14 element or group-15 element of the periodic table instead of arsenic (As).

In the illustrated embodiment of FIG. 1, the memory cell MC shows a stacked structure of the first electrode layer 130, the selector layer 140, the second electrode layer 150, the memory layer 160, and the third electrode layer 170. However, the embodiments of the present disclosure are not limited thereto, and the layer structure of the memory cell MC may be diversely modified. For example, at least one among the first electrode layer 130, the second electrode layer 150, and the third electrode layer 170 may be omitted. For example, the memory cell MC may include the selector layer 140, the first electrode layer 130 disposed below the selector layer 140, and the third electrode layer 170 disposed over the selector layer 140. For example, the first electrode layer 130 disposed below the selector layer 140 may include titanium nitride (TiN), and the third electrode layer 170 disposed over the selector layer 140 may include a carbon (C) electrode. Also, for example, the vertical positions of the selector layer 140 and the memory layer 160 may be switched with each other. Also, for example, the memory cell MC may further include one or more layers (not shown) to enhance the characteristics or to improve the process.

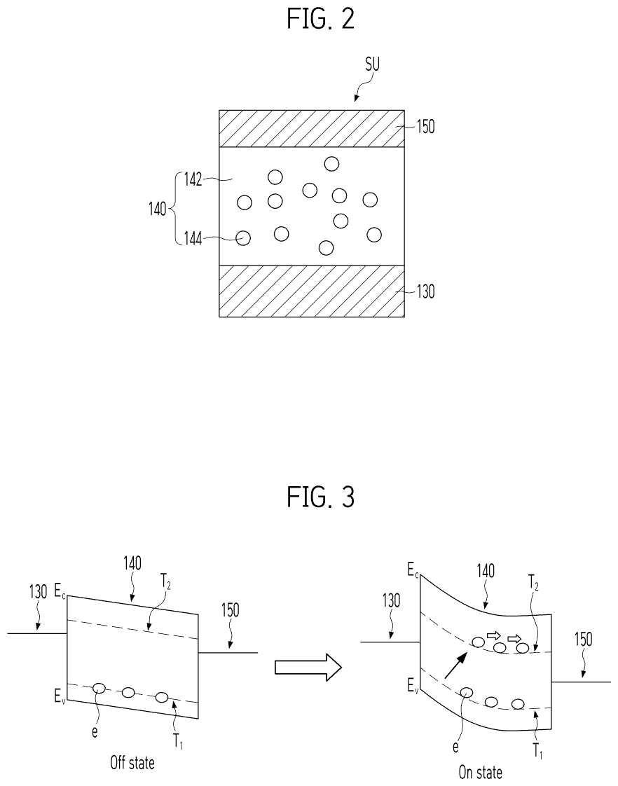

FIG. 2 is a cross-sectional view illustrating a structure of a selector unit in detail in accordance with the embodiment of the present disclosure.

Referring to FIG. 2, the selector unit SU may include the first electrode layer 130, the selector layer 140, and the second electrode layer 150.

As described above, the first electrode layer 130 and the second electrode layer 150 may include diverse conductive materials, such as metals, metal nitrides, and the like. The first electrode layer 130 and the second electrode layer 150 may be formed of the same material, and thus may have the same work function. For example, the first electrode layer 130 and the second electrode layer 150 may include titanium nitride (TiN) having a work function of approximately 4.4 to 4.6 eV. However, the embodiments of the present disclosure are not limited thereto, and the first electrode layer 130 and the second electrode layer 150 may be formed of different materials to have different work functions.

The selector layer 140 may include an amorphous silicon layer 142, and a dopant 144 that is implanted into the amorphous silicon layer 142.

The amorphous silicon layer 142 may be a dielectric material having a relatively wide band gap, for example, a dielectric material having a band gap of approximately 5.0 eV or greater. For example, the amorphous silicon layer 142 may include a deep trap whose energy level is closer to an energy level of a valence band than to an energy level of a conduction band of a thin layer. The dopant 144 may serve to form a shallow trap that provides a path for conductive carriers, for example, electrons or holes, to move in the amorphous silicon layer 142. The shallow trap may have an energy level that is closer to the energy level of the conduction band than to the energy level of the valence band of the amorphous silicon layer 142.

The dopant 144 may include at least one selected from the group including the elements of group-13, the elements of group-14, and the group-15 elements of the periodic table having a different valence from the valence of silicon (Si).

For example, the dopant 144 may include a group-13 element of the periodic table, such as boron (B), aluminum (Al), gallium (Ga), or indium (In). For another example, the dopant 144 may include a group-14 element of the periodic table, such as carbon (C), silicon (Si), germanium (Ge), or tin (Sn), together with a group-13 element of the periodic table. For another example, the dopant 144 may include a group-15 element of the periodic table, such as nitrogen (N), phosphorus (P), arsenic (As), or antimony (Sb), together with a group-13 element of the periodic table. For another example, the dopant 144 may include boron (B), and may further include one or more among phosphorus (P) and arsenic (As) together with boron (B).

The concentration of the dopant and the ratio of amorphous silicon in the doped amorphous silicon layer may vary greatly according to the process conditions. The concentration of the dopant may be controlled by controlling the flow rates and hydraulic pressures of diborane (B₂H₆) and silane gas (SiₓH_{y}). For example, increasing the flow rate of diborane may increase the concentration of the dopant, and conversely, increasing the flow rate of silane gas may increase the ratio of amorphous silicon. When the doped amorphous silicon layer is generated by reacting diborane and silane gas under the temperature conditions of approximately 300° C., the dopant 144 may have a concentration of approximately 10 to 30 wt %, and the amorphous silicon may have a concentration of approximately 90 to 70 wt % in the doped amorphous silicon layer. When the doped amorphous silicon layer is formed by reacting diborane and silane gases under the temperature conditions of approximately 400° C., the diffusion of the dopant may become more active so that the amorphous silicon layer may be doped with the dopant more easily. Accordingly, in this case, in the doped amorphous silicon layer, the dopant 144 may have a concentration of approximately 30 to 90 wt %, and the amorphous silicon may have a concentration of approximately 70 to 10 wt %.

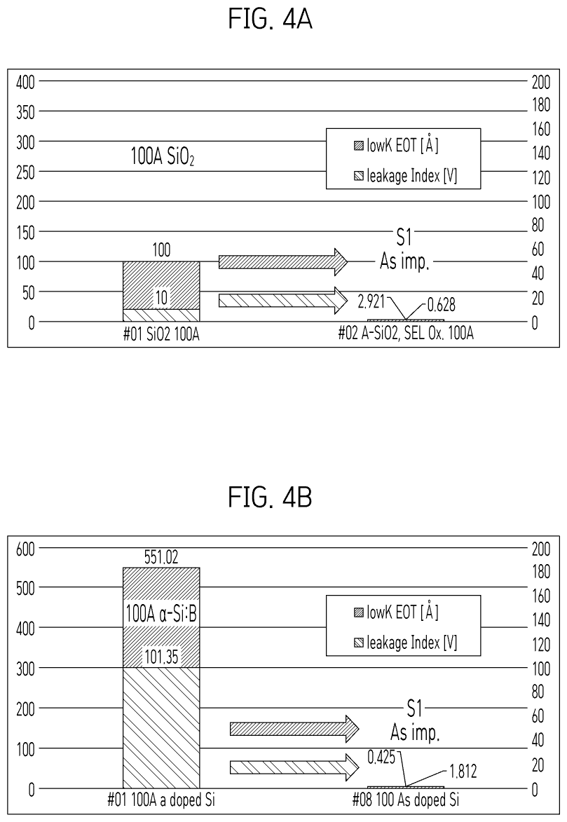

FIG. 3 illustrates an operation of the selector unit SU shown in FIG. 2.

Referring to FIG. 3, in an off state where no voltage is applied to the selector layer 140, a conductive carrier, for example, an electron (e), may be trapped in a deep trap T1 of the selector layer 140.

When a voltage greater than or equal to the threshold voltage level is applied to the selector layer 140 of the off state through the first electrode layer 130 and the second electrode layer 150, an on state in which current flows through the selector layer 140 may be realized. To be specific, when a voltage greater than or equal to the threshold voltage level is applied to the selector layer 140, conductive carriers trapped in the deep trap T1 may jump into a shallow trap T2 by a thermal emission process or a tunneling process, and the conductive carriers may move through the shallow trap T2 to create a conductive path that couples the first electrode layer 130 and the second electrode layer 150.

When the voltage applied to the selector layer 140 of the on state is decreased, the number of the conductive carriers moving from the deep trap T1 to the shallow trap T2 may also be decreased, so that the selector layer 140 may be turned off again.

In this way, the selector layer 140 may be turned on and off.

When the selector layer 140 includes crystalline silicon oxide, strong scattering may occur due to the bonding of silicon (Si) and oxygen (O), and the possibility that a cluster is formed may be increased. Scattering refers to a phenomenon in which electrons change their direction or speed by interacting with other physical objects in a semiconductor material or device. Electron scattering may have a significant influence on determining the path that electrons move and determining the electrical characteristics. A cluster may refer to a group of atoms or molecules existing in a semiconductor material or structure. These clusters may have a significant influence on the characteristics of semiconductor devices, and often affect the performance or stability of the devices. Clusters may cause dispersion of key performance indicators (KPI), namely, they may cause instability in the production process.

In order to solve this concern, according to one embodiment of the present disclosure, amorphous silicon may be used instead of the existing silicon oxide or silicon nitride as the selector layer 140, and a group-13 element, a group-14 element, and/or a group-15 element of the periodic table may be doped into the amorphous silicon. As a result, according to the embodiment of the present disclosure, the occurrence of clusters in the selector layer may be suppressed, and the dispersion of the KPI may be reduced.

According to the embodiment of the present disclosure, the following advantages may be obtained compared to a comparative example. Herein, the comparative example corresponds to a case where the selector layer is formed by ion-implanting arsenic (As) into silicon oxide.

According to the embodiment of the present disclosure, a conductive path may be formed in the vacancy of the lacking valence of 1 by doping amorphous silicon, which is a group-14 element of the periodic table, with a first dopant, which is a group-13 element of the periodic table; and conductivity may be given to the amorphous silicon layer to form a leaky path with similar conductivity by ion-implanting a second dopant, which is a group-14 element or a group-15 element of the periodic table. Also, these elements may secure sensitive electrical characteristics as the selector layer by being chemically cross-linked with each other, and may also prevent inter-diffusion, improve heat dissipation, and improve electrode stability. Also, the insulating and conductivity characteristics of the selector layer may be easily controlled by controlling the ion implantation energy of the second dopant.

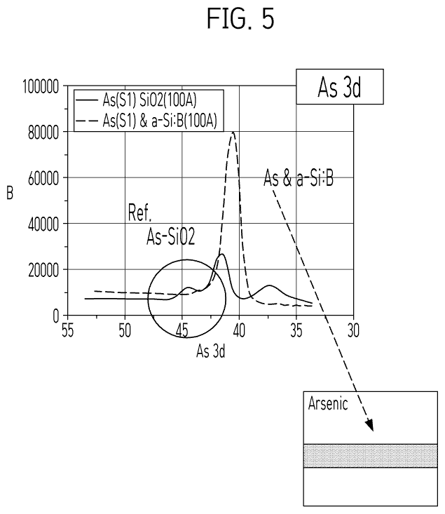

FIG. 4A shows the Equivalent Oxide Thickness (EOT) and leakage index of silicon oxide. FIG. 4B shows the equivalent oxide thickness and leakage index of boron (B)-doped amorphous silicon. Referring to FIGS. 4A and 4B, it may be seen that boron (B)-doped amorphous silicon intrinsically has an insulating property and shows a large equivalent oxide thickness and leakage index compared to those of silicon oxide, and also shows excellent insulating property in the off state. Also, amorphous silicon has excellent uniformity and a stable state by low-temperature deposition.

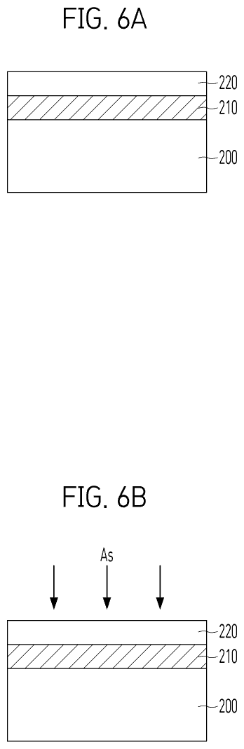

FIG. 5 is a graph showing the dispersion of constituent elements according to X-ray photoelectron spectroscopy (XPS) and electron energy loss spectroscopy (EELS) of a sample of silicon oxide into which arsenic (As) is ion-implanted, which is used for a typical selector, according to the comparative example (i.e., solid line), and a sample of boron (B)-doped amorphous silicon into which arsenic (As) is ion-implanted according to the embodiment of the present disclosure (i.e., dotted lines). It may be seen from the graph that the arsenic (As) profile uniformity of the embodiment of the present disclosure is significantly superior to that of the comparative example.

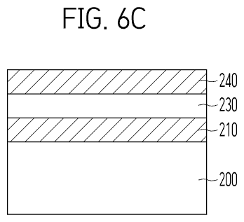

FIGS. 6A to 6C show a method for fabricating a semiconductor device in accordance with an embodiment of the present disclosure.

Referring to FIG. 6A, a substrate 200 having a predetermined lower structure may be provided. The substrate 200 may include diverse required circuits. For example, the substrate 200 may include a conductive line which is similar to the first conductive line 110 of FIG. 1.

Subsequently, a first electrode layer 210 may be formed over the substrate 200. The first electrode layer 210 may be formed as a TiN thin layer.

Subsequently, an amorphous silicon layer doped with a dopant may be formed over the first electrode layer 210 as an initial selector layer 220. Forming the amorphous silicon layer doped with a dopant may be realized as a method of depositing the amorphous silicon layer that is doped with a first dopant. The first dopant may include a group-13 element of the periodic table, such as boron (B), aluminum (Al), gallium (Ga), or indium (In). In one embodiment, the first dopant may be boron (B).

The amorphous silicon layer having the first dopant may be formed by a Low-Pressure Chemical Vapor Deposition (LPCVD) process using a first dopant-containing catalyst and a silicon source gas. For example, the amorphous silicon layer including the first dopant may be formed by the low-pressure chemical vapor deposition (LPCVD) process using silane gas (SiₓH_{y}), such as SiH₄, and diborane (B₂H₆). The low-pressure chemical vapor deposition process may provide a uniform thin layer and a low defect rate, thereby improving the performance of the semiconductor device.

When boron (B) is applied as the first dopant, the boron-containing catalyst may be a material selected from the group consisting of trimethyl borate (B(Ome)₃), boron trichloride (BCl₃), boron tribromide (BBr₃), boron dibromide (BBr₂), boron trifluoride (BF₃), and diborane (B₂H₆). In the case of a boron (B)-containing catalyst that does not contain hydrogen in itself, it may be supplied together with hydrogen (H₂).

Subsequently, referring to FIG. 6B, a second dopant, for example, arsenic (As), may be ion-implanted into the amorphous silicon layer including the first dopant. In addition to arsenic (As), the second dopant may include a group-14 element of the periodic table, for example, carbon (C), silicon (Si), germanium (Ge), or tin (Sn), or a group-15 element of the periodic table, for example, nitrogen (N), phosphorus (P), or antimony (Sb). In one embodiment, the first dopant may include boron (B), and the second dopant may include one or more selected from the group including carbon (C), silicon (Si), germanium (Ge), phosphorus (P), and arsenic (As). The ion implantation process of the second dopant may be performed in a direction substantially perpendicular to the surface of the substrate 200. For example, a tilted ion implantation process may be used. Also, the ion implantation process may be performed repeatedly several times. A semiconductor device may be given with electrical characteristics by ion-implanting a second dopant such as arsenic (As) into the amorphous silicon layer. The characteristics of the semiconductor device may be appropriately changed by changing the concentration of the ion-implanted second dopant. For example, the concentration may be adjusted from approximately 10% to 50% according to the implantation conditions.

In some embodiments, the ion-implantation process of the second dopant described through FIG. 6B may be omitted in the process of realizing the selector layer 230 of the present disclosure. It is possible to fabricate a semiconductor device suitable for a particular purpose and characteristic only with the amorphous silicon layer into which the first dopant is implanted as the selector layer 230.

An amorphous silicon layer into which the second dopant is additionally ion-implanted may be easily secured, and a conductive path in the amorphous silicon layer may be easily secured due to the second dopant impact during the ion-implantation process.

Subsequently, referring to FIG. 6C, a second electrode layer 240 may be formed over the amorphous silicon layer including the first and/or second dopant as the selector layer 230. The second electrode layer 240 may be formed by a deposition method of a conductive material. The second electrode layer 240 may be formed as a single TiN thin layer, or may be formed by stacking a carbon (C) thin layer and a TiN layer. In one embodiment, the carbon (C) thin layer may be formed between the amorphous silicon layer and the TiN layer.

The amorphous silicon layer including the first and/or second dopant as the selector layer 230 in accordance with an embodiment of the present disclosure may have to exist in the amorphous state in the final result of the fabricated semiconductor device. Typically, a high temperature process of approximately 400° C. or greater may not be accompanied when a variable resistance memory element is formed. For this reason, in the semiconductor device of the final result which is fabricated in accordance with an embodiment of the present disclosure, the amorphous silicon layer as a selector may exist in the amorphous state which is not crystallized.

The semiconductor device according to the embodiment of the present disclosure may be fabricated through the process described above.

Referring back to FIG. 6C, the semiconductor device in accordance with the embodiment of the present disclosure may include the substrate 200, the first electrode layer 210 over the substrate 200, and the selector layer 230 and the second electrode layer 240 that are sequentially formed over the first electrode layer 210.

According to the embodiment of the present disclosure, a semiconductor device and a method for fabricating the semiconductor device may have improved selector characteristics of memory cells.

While the embodiments of the present disclosure have been described with respect to the specific embodiments, it will be apparent to those skilled in the art that various changes and modifications may be made without departing from the spirit and scope of the disclosure as defined in the following claims. Furthermore, the embodiments may be combined to form additional embodiments.

What is claimed is:

1. A semiconductor device comprising:
a plurality of memory cells,
wherein each of the memory cells includes:
a memory layer; and
a selector layer formed over or below the memory layer to select the memory layer, and
wherein the selector layer includes an amorphous silicon layer having at least one dopant selected from a group including group-13 elements, group-14 elements, and group-15 elements of periodic table.

2. The semiconductor device of claim 1, wherein the dopant includes a group-13 element of the periodic table.

3. The semiconductor device of claim 1, wherein the dopant includes a group-13 element and a group-14 element of the periodic table.

4. The semiconductor device of claim 1, wherein the dopant includes a group-13 element and a group-15 element of the periodic table.

5. The semiconductor device of claim 1, wherein the dopant includes boron (B).

6. The semiconductor device of claim 1, wherein the dopant includes at least one of phosphorus (P) and arsenic (As), and boron (B).

7. The semiconductor device of claim 1, wherein the dopant includes
at least one selected from a group including carbon (C), silicon (Si), and germanium (Ge), and boron (B).

8. The semiconductor device of claim 1, wherein the dopant has a concentration of approximately 10 to 30 wt % in the amorphous silicon layer.

9. The semiconductor device of claim 1, wherein the dopant has a concentration of approximately 30 to 90 wt % in the amorphous silicon layer.

10. The semiconductor device of claim 1, wherein the memory cell further includes
a first electrode layer disposed below the selector layer, and
a second electrode layer disposed over the selector layer.

11. The semiconductor device of claim 10, wherein each of the first electrode layer and the second electrode layer include a titanium nitride (TiN) thin layer.

12. The semiconductor device of claim 10, further comprising:
a silicon nitride (SiN) thin layer formed between the first electrode layer and the selector layer, and
a carbon (C) thin layer formed between the selector layer and the second electrode layer.

13. A method for fabricating a semiconductor device, the method comprising:
forming an amorphous silicon layer having a dopant as a selector layer over a substrate, the selector layer configured to control electrical access to one memory cell among a plurality of memory cells that are arrayed; and
performing a thermal process on the amorphous silicon layer at a temperature less than or equal to a temperature at which the amorphous silicon layer is crystallized.

14. The method of claim 13, wherein forming the amorphous silicon layer includes
depositing the amorphous silicon layer that is doped with a first dopant.

15. The method of claim 14, wherein the first dopant has a concentration of approximately 10 to 30 wt % in the amorphous silicon layer.

16. The method of claim 13, further comprising:
forming an electrode layer over the selector layer.

17. The method of claim 13, wherein forming the amorphous silicon layer includes
depositing an amorphous silicon layer that is doped with a first dopant; and
ion-implanting a second dopant into the amorphous silicon layer doped with the first dopant.

18. The method of claim 13, wherein the first dopant includes a group-13 element of periodic table, and
the second dopant includes a group-14 element or a group-15 element of the periodic table.

19. The method of claim 13, wherein the first dopant includes boron (B), and
the second dopant includes at least one selected from a group including carbon (C), silicon (Si), germanium (Ge), phosphorus (P), and arsenic (As).

20. The method of claim 13, wherein the thermal process is performed at a temperature of approximately 400° C. or less.

21. The method of claim 13, wherein the dopant has a concentration of approximately 30 to 90 wt % in the amorphous silicon layer.

22. The method of claim 14, wherein the depositing of the amorphous silicon layer that is doped with the first dopant is performed by a low-pressure chemical vapor deposition (LPCVD) process using SiH₄ and diborane (B₂H₆).
